(19) United States
(12) Patent Application Publication
(10) Pub. No.: US 2024/0219617 A1
(43) Pub. Date: Jul. 4, 2024

(54) LIGHT CONTROL FILM AND DISPLAY DEVICE INCLUDING SAME

(71) Applicant: LG Display Co., Ltd, Seoul (KR)

(72) Inventors: Wonjong CHO, Gyeonggi-do (KR); HyunJong NOH, Gyeonggi-do (KR)

(73) Assignee: LG Display Co., Ltd, Seoul (KR)

(21) Appl. No.: 18/535,786

(22) Filed: Dec. 11, 2023

(30) Foreign Application Priority Data
Dec. 30, 2022 (KR) 10-2022-0190034

(51) Int. Cl. G02B 5/30; H10K 59/80

(52) U.S. Cl. CPC G02B 5/3083; H10K 59/8792

(57) ABSTRACT

A light control film includes an obliquely-stretched base, a horizontally-oriented dye layer disposed on the obliquely-stretched base and including dyes and a horizontal alignment film integrated with the dyes, and an anti-reflection layer disposed on the horizontally-oriented dye layer, and black vision in an off state is improved by reducing the reflectance of external light.

### CROSS-REFERENCE TO RELATED APPLICATION

This application claims the priority of Korean Patent Application No. 10-2022-0190034, filed on Dec. 30, 2022, which is hereby incorporated by reference in its entirety.

### BACKGROUND

### Field of the Disclosure

Aspects relate to a light control film and more particularly, for example, without limitation, to a light control film including a horizontally-oriented dye layer having dyes and a horizontal alignment film integrated with the dyes and, a display device including the same.

### Description of the Background

Recently, flat panel displays including a liquid crystal display (LCD), an organic light-emitting diode (OLED) display, a plasma display panel (PDP), and the like have been used as image display devices.

OLED displays are self-light-emitting devices that emit light via an organic light-emitting layer through recombination of electrons and holes, and are expected as next-generation display devices, due to having high luminance, low driving voltage, and ultra-thin features.

In a typical OLED display, contrast is significantly reduced by reflection from a variety of conductive lines or electrodes formed of metal. Thus, to prevent this problem, a circular polarizer is located on the top surface of a display panel.

However, when the circular polarizer is located on the top surface of the display panel, the overall luminance of the OLED display may also be reduced. That is, since the transmittance of the circular polarizer is about 40% to 50%, the luminance of light generated by OLEDs is reduced by 50% or more while passing through the circular polarizer.

The above information disclosed in this Background section is only for enhancement of understanding of the background of the described technology and therefore it may contain information that does not form prior art that is already known to a person of ordinary skill in the art.

### SUMMARY

Thus, an anti-reflection film including a light absorption layer has recently been located on the top surface of the display panel, in place of the circular polarizer, in order to overcome this problem of the overall luminance of the OLED display being reduced due to the use of the circular polarizer. In an OLED display provided with an anti-reflection film, when light enters the display device through the front, reflection from the display device is prevented, thereby reducing the reflectance of external light. However, as recognized by the inventors, in an off state, scattering reflectance increases. When light enters through a side of the viewing angle of the display device, reflection of light from the display device increases. Thus, the reflectance of external light may increase when seen from the side, and the vision in an off-state, for example, black vision may be reduced. Thus, outdoor visibility and contrast ratio are reduced.

Accordingly, the present disclosure is directed to a light control film and a display device including the same that substantially obviate one or more of problems due to limitations and disadvantages described above.

More specifically, the present disclosure is to provide a light control film and a display device having improved black vision in an off state by reducing the reflectance of external light.

The present disclosure is also to provide a light control film and a display device having improved outdoor visibility and contrast ratio by reducing the reflectance of external light.

Further, the present disclosure is to provide a light control film and a display device capable of low power consumption.

To achieve these and other advantages and in accordance with the present disclosure, as embodied and broadly described, a light control film including: an obliquely-stretched base; a horizontally-oriented dye layer disposed on the obliquely-stretched base and including dyes and a horizontal alignment film integrated with the dyes; and an anti-reflection layer disposed on the horizontally-oriented dye layer.

In another aspect of the present disclosure, a display device includes a display panel; an obliquely-stretched base disposed on the display panel; a horizontally-oriented dye layer disposed on the obliquely-stretched base and including dyes and a horizontal alignment film integrated with the dyes; and an anti-reflection layer disposed on the horizontally-oriented dye layer, wherein the display panel includes a black bank defining an emission area.

Other details of various aspects are included in the detailed description and the drawings.

According to various aspects of the present disclosure, the light control film and the display device may have improved black vision in an off state by reducing the reflectance of external light.

According to various aspects of the present disclosure, the light control film and the display device may have improved outdoor visibility and contrast ratio by reducing the reflectance of external light.

According to various aspects of the present disclosure, the light control film and the display device capable of low power consumption may be provided.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description, taken in conjunction with the accompanying drawings, in which:

FIG. 1 is a diagram illustrating a system configuration of a display device according to aspects of the present disclosure;

FIG. 2 is a diagram schematically illustrating a structure of the display device according to aspects of the present disclosure;

FIG. 3 is a cross-sectional diagram illustrating the structure of an area of the display panel of the display device according to aspects of the present disclosure;

FIG. 4 is a diagram schematically illustrating a fabrication process of a horizontal alignment dye layer of the light control film according to aspects of the present disclosure;

FIG. 5 is a graph comparing black luminance values according to the luminous intensity of display devices according to Examples of the present disclosure and of display devices according to Comparative Examples; and

FIG. 6 is a cross-sectional diagram schematically illustrating another structure of the display device according to aspects of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or aspects of the present disclosure, reference will be made to the accompanying drawings in which it is shown by way of illustration specific examples or aspects that may be implemented, and in which the same reference numerals and signs may be used to designate the same or like components even when they are shown in different accompanying drawings from one another. The shapes, sizes, areas, ratios, angles, numbers, and the like illustrated in the accompanying drawings for describing various embodiments of the present disclosure are may be merely examples, and the present disclosure is not limited thereto. Further, in the following description of examples or aspects of the present disclosure, detailed descriptions of well-known functions and components incorporated herein will be omitted when it is determined that the description may make the subject matter in some aspects of the present disclosure rather unclear. Furthermore, the present disclosure is not limited to the embodiment to be disclosed below and is implemented in different and various forms. The embodiments bring about the complete disclosure of the present disclosure and are only provided to make those skilled in the art understand the scope of the present disclosure. Further, the present disclosure is only defined by the scope of the claims and their equivalents.

The terms such as “including”, “having”, “comprising”, “containing”, “constituting” “make up of”, “formed of” and “consist of” used herein are generally intended to allow other components to be added unless the terms are used with the term such as “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only may the first element “be directly connected or coupled to” or “directly contact or overlap” the second element, but a third element may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap”, etc. each other.

When the position relation between two parts is described using the terms such as “on”, “above”, “over”, “below”, “under”, “beside”, “beneath”, “near”, “close to,” “adjacent to”, “on a side of”, “next” or the like, one or more parts may be positioned between the two parts unless the terms are used with the term such as “immediately” or “directly”.

Spatially relative terms, such as “under,” “below,” “beneath”, “lower,” “over,” “upper” and the like, may be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When time relative terms, such as “after”, “subsequent to”, “following”, “next”, “before”, and the like, are used to describe processes or operations of elements or configurations, or flows or steps in operating, processing, manufacturing methods, these terms may be used to describe non-consecutive or non-sequential processes or operations unless the term such as “directly”, “just” or “immediately” is used together.

In addition, when any dimensions, relative sizes etc. are mentioned, it should be considered that numerical values for an elements or features, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may”.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include an organic light emitting diode (OLED), and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including OLED and the like, but embodiments of the present disclosure are not limited thereto.

A size and a thickness of each component illustrated in the drawing are illustrated for convenience of description, and the present disclosure is not limited to the size and the thickness of the component illustrated.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, a light control film and a display device including the light control film according to aspects of the present disclosure will be described with reference to the accompanying drawings.

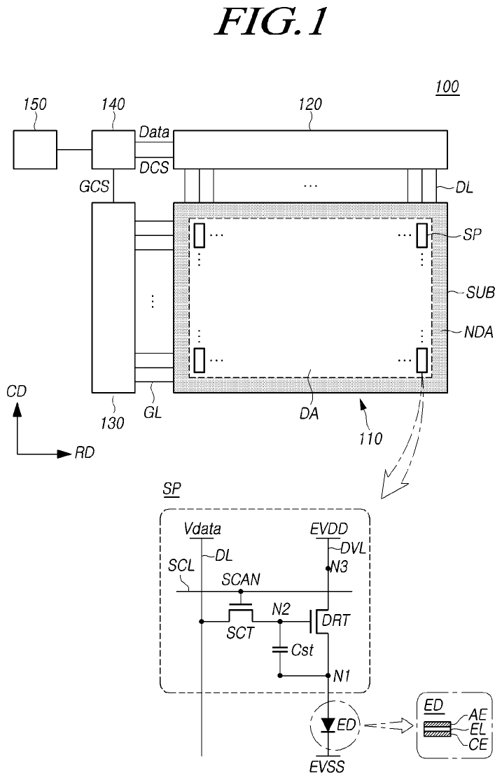

FIG. 1 is a diagram illustrating a system configuration of a display device 100 according to aspects of the present disclosure. All the components of each display device according to all embodiments of the present disclosure are operatively coupled and configured. Referring to FIG. 1, a display driver system of the display device 100 according to aspects of the present disclosure may include a display panel 110 and a display driver circuit for driving the display panel 110.

The display panel 110 may include a display area DA on which images are displayed and a non-display area NDA on which no images are displayed. The non-display area NDA may be disposed in the vicinity of the display area DA or surrounding the display area DA. The display panel 110 may include a plurality of subpixels SP arranged on a substrate SUB to display images. The substrate SUB may include glass, plastic, or a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC) film, polyvinyl alcohol (PVA) film, and polystyrene (PS), and the present disclosure is not limited thereto.

The display panel 110 may include a plurality of signal lines disposed on the substrate SUB. For example, the plurality of signal lines may include data lines DL, gate lines GL, driving voltage lines, and the like.

Each of the plurality of data lines DL extend in a first direction (e.g., a column direction (CD) or a row direction (RD)). Each of the plurality of gate lines GL may extend in a direction (e.g., a row direction or a column direction) intersecting the first direction.

The display driver circuit may further include a data driver circuit 120, a gate driver circuit 130, and a controller 140 for controlling the data driver circuit 120 and the gate driver circuit 130.

The data driver circuit 120 may output data signals (also referred to as data voltages) corresponding to image signals to the plurality of data lines DL. The gate driver circuit 130 may generate gate signals and sequentially output the gate signals to the plurality of gate lines GL under control of the controller 140. The controller 140 may convert image data input from an external host 150 into a data signal format readable by the data driver circuit 120 and supply the converted image data to the data driver circuit 120.

The data driver circuit 120 may include one or more source driver integrated circuits. For example, each of the more source driver integrated circuits may be connected to the display panel 110 using a tape-automated bonding (TAB) structure, connected to bonding pads of the display panel 110 using a chip-on-glass (COG) structure or a chip-on-panel (COP) structure, or formed and connected to the display panel 110 using a chip-on-film (COF) structure.

The gate driver circuit 130 may be disposed on one side or both sides of the display panel 110 using a TAB structure, a COG structure or a COP structure, or formed in the non-display area NDA of the display panel 110 using a gate-in-panel (GIP) structure.

Referring to FIG. 1, in the display device 100 according to aspects of the present disclosure, each of the subpixels SP may include a light-emitting element ED and a pixel driver circuit SPC for driving the light-emitting element ED. The pixel driver circuit SPC may include a driving transistor DRT, a scan transistor SCT, and a storage capacitor Cst.

The driving transistor DRT may drive the light-emitting element ED by controlling current flowing to the light-emitting element ED. The scan transistor SCT may transfer a data voltage Vdata to a second node N2, i.e., a gate node, of the driving transistor DRT. The storage capacitor Cst may be configured to maintain a voltage for a predetermined period of time.

The light-emitting element ED may include an anode AE, a cathode CE, and a light-emitting layer EL located between the anode AE and the cathode CE. The anode AE may be a pixel electrode involved in formation of the light-emitting element ED each of the subpixels SP, and may be electrically connected to the first node N1 of the driving transistor DRT. The cathode CE may be a common electrode involved in formation of the light-emitting element ED of the entirety of the subpixels SP, and may be provided with a base voltage EVSS.

For example, the light-emitting element ED may be an organic light-emitting diode (OLED), an inorganic light-emitting diode (LED), a quantum dot serving as a self-light-emitting semiconductor crystal, or the like, and embodiments of the present disclosure are not limited thereto.

The driving transistor DRT is a transistor for driving the light-emitting element ED, and may include the first node N1, a second node N2, a third node N3, and the like. The first node N1 may be a source node or a drain node, and may be electrically connected to the anode AE of the light-emitting element ED. The second node N2 may be a gate node, and may be electrically connected to a source node or a drain node of the scan transistor SCT. The third node N3 may be a drain node or a source node, and may be electrically connected to a driving voltage line DVL through which a driving voltage EVDD is supplied. Hereinafter, a case in which the first node N1 is a source node and the third node N3 is a drain node will be described as an example for the convenience of description. However, embodiments of the present disclosure are not limited thereto, for example, the first node N1 may be a drain node and the third node N3 may be a source node.

The scan transistor SCT may switch the connection between a data line DL and the second node N2 of the driving transistor DRT. The scan transistor SCT may control the connection between the second node N2 of the driving transistor DRT and a corresponding data line DL among the plurality of data lines DL, in response to a scan signal SCAN supplied through a scan line SCL that is a type of gate line GL.

The storage capacitor Cst may be provided between the first node N1 and the second node N2 of the driving transistor DRT.

The structure of the subpixel SP illustrated in FIG. 1 is provided for illustrative purposes only, the present disclosure is not limited to the circuit diagram of the subpixel SP shown in FIG. 1 and various configurations of internal compensation circuits are possible. For example, the structure of the subpixel SP of the present disclosure may further include one or more transistors or one or more capacitors and the one or more transistors may be thin film transistors TFT. For example, a number of TFTs in the structure of the subpixel SP of the present disclosure may be three or more, and a number of capacitors may be one or more, for example, the structure of the subpixel SP of the present disclosure also may be a 3T1C circuit including three TFTs and one capacitor, a 3T2C circuit including three TFTs and two capacitors, a 5T1C circuit including five TFTs and one capacitor, a 5T2C circuit including five TFTs and two capacitors, a 7T2C circuit including seven TFTs and two capacitors, or the like. Meanwhile, respective subpixels of the plurality of subpixels may have the same structure, or some subpixels of the plurality of subpixels may have a different structure. Each of the driving transistor DRT and the scan transistor SCT may be an N-type transistor or a P-type transistor. In the case of an N-type transistor, the gate-on voltage may be a gate-high voltage, and the gate-off voltage may be a gate-low voltage. In the case of a P-type transistor, the gate-on voltage may be the gate-low voltage and the gate-off voltage may be the gate-high voltage.

In addition, the display device 100 according to aspects of the present disclosure may have a top emission structure or a bottom emission structure.

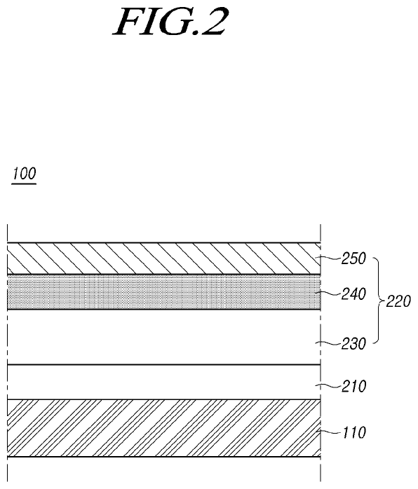

FIG. 2 is a diagram schematically illustrating a structure of the display device according to aspects of the present disclosure.

Referring to FIG. 2, the display device 100 according to aspects of the present disclosure may include the display panel 110 and a light control film 220 disposed on the display panel 110. The light control film 220 may include an obliquely-stretched base 230, a horizontally-oriented dye layer 240, and an anti-reflection layer 250. The display device 100 may further include a bonding layer 210 between the display panel 110 and the light control film 220.

The bonding layer 210 may be implemented as an adhesive material, for example, an optical clear adhesive (OCA), a pressure sensitive adhesive (PSA), thermally Conductive Adhesive (TCA), UV-Curable Adhesive, Light-cured optical adhesive, Structural optical adhesive (SOA) or the like, but is not limited thereto.

Specifically, the obliquely-stretched base 230 may be disposed on the display panel 110 via the bonding layer 210.

The optical axis of the obliquely-stretched base 230 may range from 30° to 60°. Particularly, the optical axis of the obliquely-stretched base 230 may be 45°. The obliquely-stretched base 230 may have a plane-direction phase retardation value (Rin) of 137 nm to 147 nm. For example, the plane-direction phase retardation value Rin may be from 140 nm to 144 nm.

The obliquely-stretched base 230 may be a base materials including cyclo-olefin polymer (COP), tri-acetyl cellulose (TAC), an acrylic or the like, and the present disclosure is not limited thereto.

The horizontally-oriented dye layer 240 may be disposed on the obliquely-stretched base 230.

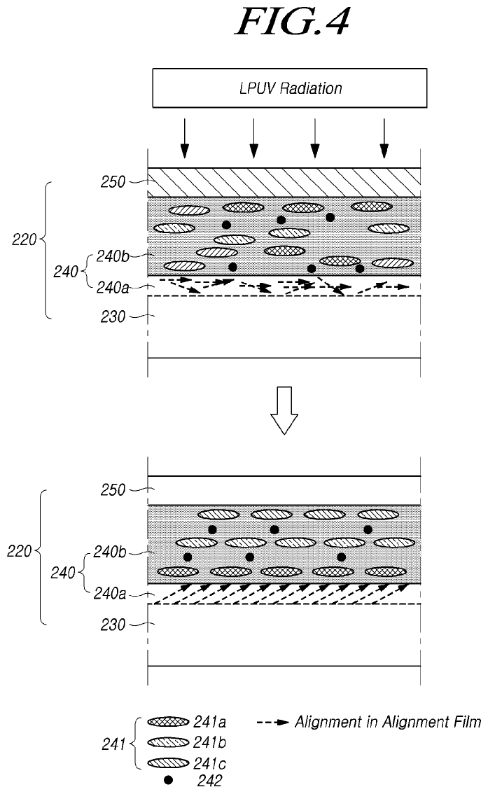

Referring to FIG. 4, the horizontally-oriented dye layer 240 may include a horizontal alignment film 240a and a dye layer 240b.

The dye layer 240b may include dyes 241 in a binder resin.

The binder resin may include a photocurable resin. The photocurable resin refers to a polymer of a photopolymerizable compound capable of polymerization when exposed to light such as ultraviolet (UV) radiation. For example, the photocurable resin may be an acrylate-based resin, but the present disclosure is not limited thereto.

The dye layer 240b may include a photoinitiator 242 as a catalyst to increase the rate of polymerization of the photocurable resin.

The horizontally-oriented dye layer 240 may include the dyes 241. The dyes 241 may include three different types of dyes. The dyes 241 may include three different types of dyes such as a first dye 241a, a second dye 241b, and a third dye 241c.

The three types of dyes 241a, 241b, and 241c may be selected from the group consisting of dye red (R), dye green (G), dye blue (B), dye cyan, dye magenta, or dye yellow.

Alternatively, The dyes 241 may also include less than or more than three different types of dyes. For example, the dyes 241 may include n different types of dyes, where n is an integer. The n types of dyes may be selected from the group consisting of dye red (R), dye green (G), dye blue (B), dye cyan, dye magenta, or dye yellow, and the present disclosure is not limited thereto.

The horizontally-oriented dye layer 240 may additionally include an additive. For example, an antistatic agent, a chain transfer agent, a surfactant, a plasticizer, a leveling agent, an antioxidant, a corrosion inhibitor, and the like may be properly used according to the use, and the present disclosure is not limited thereto.

The single transmittance of the horizontally-oriented dye layer 240 may range from 60% to 80%. In addition, the degree of polarization of the horizontally-oriented dye layer 240 may range from 20% to 60%.

The horizontally-oriented dye layer 240 may realize both the polarization function of a linear polarizer and the transmittance enhancement function of a luminance enhancement film of the related art, due to the dyes and the horizontal alignment film being integrated therein.

The anti-reflection layer 250 may be disposed on the horizontally-oriented dye layer 240.

The anti-reflection layer 250 may change a wavelength indicative of the minimum reflectance to reduce the impression of a color for a specific wavelength reflected from the display panel 110. For example, when the reflectance of the display panel 110 for a 650 nm wavelength is higher than the reflectance of the display panel 110 for a 450 nm wavelength, the anti-reflection layer 250 may be reformed in a direction in which the reflectance for the 650 nm wavelength is minimized.

In addition, the display panel 110 of the display device 100 according to aspects of the present disclosure may be any of various types of display panels.

For example, the display panel 110 may be a display panel 110 including a plurality of electrodes and organic light-emitting elements, i.e., self-light-emitting elements. However, embodiments of the present disclosure are not limited thereto, for example, the display panel 110 may also be a display panel 110 including a plurality of electrodes, and inorganic light-emitting elements or quantum dots or the like.

The structure of the display panel 110 according to aspects of the present disclosure will be described in detail as follows.

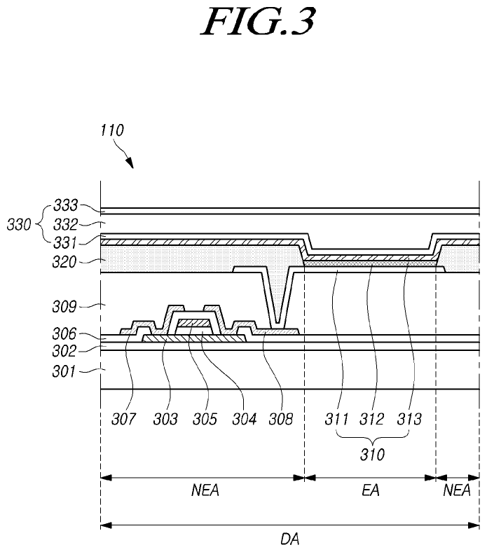

FIG. 3 is a cross-sectional diagram illustrating the structure of an area of the display panel of the display device according to aspects of the present disclosure.

Referring to FIG. 3, the display panel 110 of the display device according to aspects of the present disclosure may include a display area DA on which images are displayed and a non-display area, i.e., the remaining area except for the display area DA.

The display panel 110 may include at least one thin-film transistor (TFT) disposed on a substrate 301 and an organic light-emitting element 310 disposed on the TFT.

The TFT may include an active layer 303, a gate electrode 305, a source electrode 307, and a drain electrode 308. For example, the gate electrode 305 may be formed of a conductive material, for example, copper Cu, aluminum Al, molybdenum Mo, nickel Ni, titanium Ti, chromium Cr, or an alloy thereof, but not limited thereto.

The organic light-emitting element 310 may include a first electrode 311, a light-emitting layer 312, and a second electrode 313. For example, the light-emitting layer 312 may include one or more of a hole injection layer (HIL), a hole transmitting layer (HTL), an electron transmitting layer (ETL) and an electron injection layer (EIL), but the present disclosure is not limited thereto.

Specifically, a buffer layer 302 may be disposed on the substrate 301.

The buffer layer 302 may include an inorganic insulating material, such as silicon oxide (SiOx), silicon nitride (SiNx), and silicon oxynitride (SiON), but the present disclosure is not limited thereto.

Although the buffer layer 302 is illustrated as having a single-layer structure in FIG. 3, the buffer layer 302 according to the present disclosure may have a double-layer structure or a multilayer structure with more than two lays.

When the buffer layer 302 has a double-layer structure, each the inorganic insulating material layer is formed of an inorganic insulating material selected from among the inorganic insulating materials, such as silicon oxide (SiOx), silicon nitride (SiNx), or silicon oxynitride (SiON).

When the buffer layer 302 has a multilayer structure, at least three inorganic insulating material layers each formed of an inorganic insulating material selected from among the inorganic insulating materials, such as silicon oxide (SiOx), silicon nitride (SiNx), and silicon oxynitride (SiON), may alternate in the multilayer structure, but the present disclosure is not limited thereto.

In the following, the buffer layer 302 will be described as having a single-layer structure for the sake of brevity.

The active layer 303 of the TFT may be disposed on the buffer layer 302.

The active layer 303 may be any of various types of semiconductor layers. For example, the active layer 303 may be formed of one selected from among oxide semiconductor material, amorphous semiconductor material, or polycrystalline semiconductor material, but the present disclosure is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polysilicon, but is not limited thereto.

The amorphous semiconductor may be made of amorphous silicon (Si), but is not limited thereto.

A gate insulating film 304 may be disposed between the active layer 303 and gate electrode 305.

The gate insulating film 304 may include an inorganic insulating material, such as silicon oxide (SiOx), silicon nitride (SiNx), and silicon oxynitride (SiON), but the present disclosure is not limited thereto. The gate insulating film 304 is an insulating layer for insulating the active layer 303 and gate electrode 305 from each other, and may be composed of a single layer or multilayers of silicon oxide SiOx or silicon nitride SiNx, but not limited thereto.

Although FIG. 3 illustrates a structure in which the gate insulating film 304 is disposed on a portion of the top surface of the active layer 303, the present disclosure is not limited thereto. Alternatively, the gate insulating film 304 may be disposed to cover the entire active layer 303.

The gate electrode 305 of the TFT may be disposed on the gate insulating film 304.

The gate electrode 305 may include one of aluminum (Al), gold (Au), silver (Ag), copper (Cu), tungsten (W), molybdenum (Mo), chromium (Cr), tantalum (Ta), titanium (Ti), or alloys thereof, but the present disclosure is not limited thereto.

An interlayer insulating film 306 may be disposed on the gate electrode 305.

Although the interlayer insulating film 306 may include one from among inorganic insulating materials, such as silicon oxide (SiOx), silicon nitride (SiNx), and silicon oxynitride (SiON), but the present disclosure is not limited thereto.

The source electrode 307 and the drain electrode 308 of the TFT may be spaced apart from each other while being disposed on the interlayer insulating film 306.

Alternatively, in aspects of the present disclosure, the reference numeral 307 may indicate a drain electrode, and the reference numeral 308 may indicate a source electrode.

Each of the source electrode 307 and the drain electrode 308 may include one of aluminum (Al), gold (Au), silver (Ag), copper (Cu), tungsten (W), molybdenum (Mo), chromium (Cr), tantalum (Ta), titanium (Ti), or alloys thereof, but the present disclosure is not limited thereto.

Each of the source electrode 307 and the drain electrode 308 may be connected to a portion of the top surface of the active layer 303 through a contact hole provided in the interlayer insulating film 306.

A planarization layer 309 may be disposed over substrate 301 on which the source electrode 307 and the drain electrode 308 are disposed.

Although not shown in the drawings, a passivation layer protecting the inorganic insulating material may be disposed below the planarization layer 309.

The first electrode 311 of the organic light-emitting element 310 may be disposed on a portion of the top surface of the planarization layer 309.

The first electrode 311 may be electrically connected to the drain electrode 308 of the TFT through the contact hole provided in the planarization layer 309. Although FIG. 3 illustrates a structure in which the first electrode 311 is connected to the drain electrode 308 of the TFT, the present disclosure is not limited thereto. Alternatively, the first electrode 311 may be connected to the source electrode 307 of the TFT. For example, each of the first electrode 311 and the second electrode 313 may comprise a metal material such as Au, W, Pt, Si, Ir, Ag, Cu, Ni, Ti, or Cr, and an alloy thereof.

Although the first electrode 311 is illustrated as having a single-layer structure in FIG. 3, the present disclosure is not limited thereto. For example, the first electrode 311 may have a multilayer structure comprised of two or more layers. For example, the first electrode 311 may have a multilayer structure including a transparent conductive film. The transparent conductive film may be made of a material having a relatively high work function value such as indium-tin-oxide (ITO) or indium-zinc-oxide (IZO).

The first electrode 311 may include a reflective electrode.

Specifically, when the first electrode 311 has a single-layer structure, the first electrode 311 may be a reflective electrode including a reflective conductive material.

When the first electrode 311 has a multilayer structure, at least one layer of the first electrode 311 may be a reflective electrode including a reflective conductive material. In addition, other layers than the reflective electrode may be layers formed of a transparent conductive material.

A bank 320 may be disposed on the planarization layer 309. The bank 320 may be a pixel-defining film or a pixel-defining layer, which defines an emission region of each subpixel, exposing the first electrode 311 of each sub-pixel. The bank 320 may be made of an opaque material (e.g., black material) to prevent optical interference between adjacent subpixels. In this case, the bank 320 may include a light blocking material made of color pigment, or black pigment.

The bank 320 may have a lattice structure generally in the form of a matrix above the substrate 301. The bank 320 surrounds the periphery of the first electrode 311 while exposing a portion of the first electrode 311. The bank 320 may include an open area defining an emission area EA by exposing a portion of the first electrode 311.

The bank 320 may define the emission area EA and a non-emission area NEA in the display area DA of the organic light-emitting display device 100. For example, a portion of the display area DA in which the bank 320 is disposed may be the non-emission area NEA, while a portion of the display area DA in which the bank 320 is absent may be the emission area EA.

The bank 320 may be implemented as a black bank including a black series color. For example, the black bank 320 may be formed of at least one organic insulating material selected from among black resin, graphite powder, gravure ink, black spray, or black enamel, but is not limited thereto. Due to the use of the black bank 320, a light leakage defect may be overcome. In addition, external light may be absorbed to reduce the overall reflectance of the display panel. Accordingly, a low-reflection display panel may be realized.

For example, when the black bank 320 is used in the display panel 110, the reflectance for 550 nm light may be reduced 10% or lower. Reflectance for blue wavelength light of 420 nm to 440 nm may be lower than reflectance for red wavelength light of 650 nm to 680 nm.

The light-emitting layer 312 of the organic light-emitting element 310 may be disposed on the first electrode 311.

The light-emitting layer 312 may be disposed on the top surface of the first electrode 311 exposed by the bank 320.

Although the light-emitting layer 312 is illustrated as having a single-layer structure in FIG. 3, the present disclosure is not limited thereto. The light-emitting layer 312 may be implemented as an organic layer having a multilayer structure.

The light-emitting layer 312 may generate light having at least one color from among red, green, and blue. However, the present disclosure is not limited thereto, and the light-emitting layer 312 may also generate light having other colors such as white, cyan, magenta, or yellow, etc.

The second electrode 313 of the light-emitting element 310 may be disposed over the substrate 301 on which the light-emitting layer 312 is disposed.

The second electrode 313 may include a transparent conductive material or a semi-transparent conductive material.

Although the light-emitting layer 312 is illustrated as having a single-layer structure in FIG. 3, the present disclosure is not limited thereto. The light-emitting layer 312 may have a multilayer structure comprised of two or more layers.

An encapsulation layer 330 may be disposed on the second electrode 313.

The encapsulation layer 330 may include a first encapsulation layer 331 disposed on the second electrode 313, a second encapsulation layer 332 disposed on the first encapsulation layer 331, and a third encapsulation layer 333 disposed on the second encapsulation layer 332. Here, each of the first and third encapsulation layers 331 and 333 may include an inorganic insulating material such as silicon oxide (SiOx) or silicon nitride (SiNx), and the second encapsulation layer 332 may include an organic insulating material such as acrylic resin, epoxy resin, phenolic resin, polyamide resin, or polyimide resin. However, materials of the first encapsulation layer 331, the second encapsulation layer 332 and the third encapsulation layer 333 are not limited thereto.

The first and third encapsulation layers 331 and 333 each including an inorganic insulating material may serve to prevent permeation of moisture and oxygen. The second encapsulation layer 332 including an organic insulating material may serve to delay movement of a small amount of moisture or oxygen that has permeated through the third encapsulation layer 333.

Meanwhile, the encapsulation layer 330 is not limited to three layers, for example, the encapsulation layer 330 may include n layers alternately stacked between inorganic encapsulation layer and organic encapsulation layer (where n is an integer greater than 3).

The position of the light control film 220 may be changed depending on the type of light emission of the display device 100 according to aspects of the present disclosure.

For example, when the display device 100 has a top emission structure, the light control film 220 may be disposed on the encapsulation layer 330. When the display device 100 has a bottom emission structure, the light control film 220 may be disposed below the substrate 301.

FIG. 4 is a diagram schematically illustrating a fabrication process of a horizontal alignment dye layer of the light control film according to aspects of the present disclosure.

Referring to FIG. 4, an alignment material is disposed in the alignment film 240a on the obliquely-stretched base 230, and a binder resin that is a photocurable resin is coated with a coating solution including the dyes 241 and the photoinitiator 242. Afterwards, when irradiated with linearly polarized ultraviolet light (LPUV), the alignment material is aligned in the alignment film 240a. Due to the alignment of the alignment material, the dyes 241 are aligned at the same time. As the binder resin is light polymerized due to irradiation with LPUV, the horizontally-oriented dye layer 240 is formed integrally.

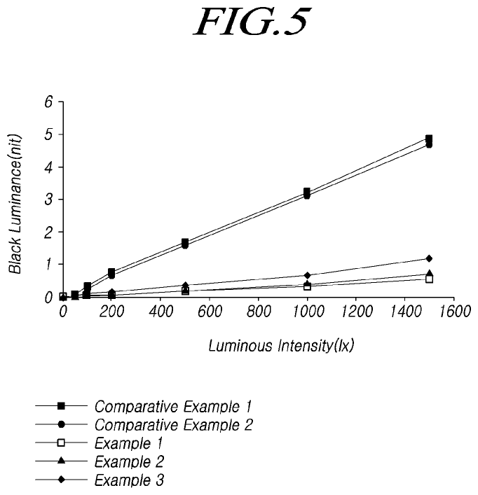

FIG. 5 is a graph comparing black luminance values according to the luminous intensity of display devices according to Examples of the present disclosure and of display devices according to Comparative Examples.

In FIG. 5, in Comparative Example 1, an ultra-low-reflection film was attached to the emission surface. In Comparative Example 2, a luminance enhancement film having a transmittance of 60% was attached to the emission surface. In display devices according to Examples 1 to 3 of the present disclosure, light control films having transmittances of 60%, 70%, and 80% were attached to the emission surfaces, respectively. In each of Comparative Examples 1 and 2 and Examples 1 to 3 of the present disclosure, a separate polarizer film was not attached.

Referring to FIG. 5, in the display devices according to Comparative Examples 1 and 2, when luminous intensity is increased, black luminance is also increased. Thus, it is difficult to realize black. In contrast, in Examples 1 to 3, even in the case in which luminous intensity is increased, black luminance is increased insignificantly. Thus, it may be determined that black is realizable.

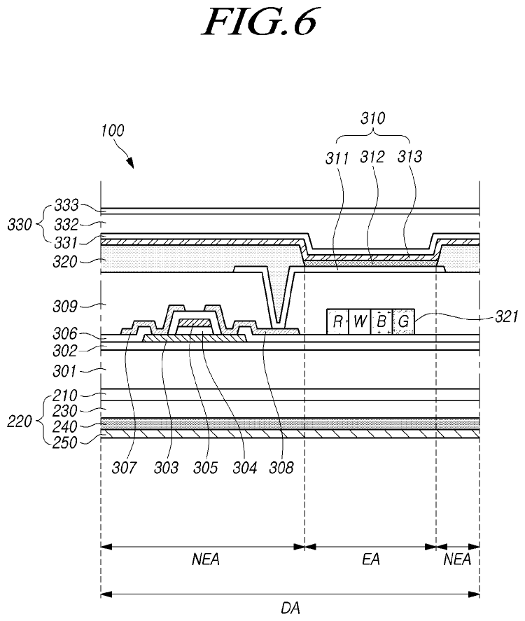

FIG. 6 is a cross-sectional diagram schematically illustrating another structure of the display device according to aspects of the present disclosure.

In FIG. 6, the display device 100 is illustrated as having a bottom emission structure by which light generated by the organic light-emitting element 310 is extracted through the substrate 301. However, aspects of the present disclosure are not limited thereto. Thus, features described in the present disclosure may be applied to either the bottom emission structure in which the light control film is disposed on the rear surface of the display panel or the top emission structure in which the light control film is disposed on the front surface of the display panel.

Referring to FIG. 6, the light control film 220 may be disposed on the rear surface of the substrate 301.

The light control film 220 may include the obliquely-stretched base 230, the horizontally-oriented dye layer 240, and the anti-reflection layer 250. The bonding layer 210 may be further included between the display panel 110 and the light control film 220.

The substrate 301 may be bonded to the light control film 220 through the bonding layer 210. The substrate 301 may be bonded to the obliquely-stretched base 230 of the light control film 220 through the bonding layer 210.

The horizontally-oriented dye layer 240 may be disposed on the rear surface of the obliquely-stretched base 230. The horizontally-oriented dye layer 240 may realize both the polarization function of a linear polarizer and the transmittance enhancement function of a luminance enhancement film of the related art, due to the dyes and the horizontal alignment film being integrated therein.

The anti-reflection layer 250 may be disposed on the horizontally-oriented dye layer 240.

The anti-reflection layer 250 may change a wavelength indicative of the minimum reflectance to reduce the impression of a color for a specific wavelength reflected from the display panel 110.

According to aspects of the present disclosure, in the light control film and the display device, the horizontal alignment dye layer integrally provided with the dyes and a horizontal alignment film is disposed and integrally provided between the obliquely-stretched base and the anti-reflection layer. Thus, the light control film and the display device may have improved black vision in an off state due to the reduced reflectance of external light.

According to aspects of the present disclosure, in the light control film and the display device, the horizontal alignment dye layer integrally provided with the dyes and a horizontal alignment film is disposed and integrally provided between the obliquely-stretched base and the anti-reflection layer. Thus, the light control film and the display device may have improved outdoor visibility and contrast ratio due to the reduced reflectance of external light.

According to aspects of the present disclosure, in the light control film and the display device, the horizontal alignment dye layer integrally provided with the dyes and a horizontal alignment film is disposed and integrally provided between the obliquely-stretched base and the anti-reflection layer. Thus, the light control film and the display device capable of low power consumption may be provided.

The above-described aspects of the present disclosure will be briefly reviewed as follows.

According to aspects of the present disclosure, provided is a light control film including: an obliquely-stretched base; a horizontally-oriented dye layer disposed on the obliquely-stretched base and including dyes and a horizontal alignment film integrated with the dyes; and an anti-reflection layer disposed on the horizontally-oriented dye layer.

In the light control film according to aspects of the present disclosure, the obliquely-stretched base may have a plane-direction phase retardation value (Rin) of 137 nm to 147 nm.

In the light control film according to aspects of the present disclosure, the obliquely-stretched base may have the plane-direction phase retardation value (Rin) of 140 nm to 144 nm.

In the light control film according to aspects of the present disclosure, an optical axis of the obliquely-stretched base may be range from 30° to 60°.

In the light control film according to aspects of the present disclosure, the optical axis of the obliquely-stretched base may be 45°.

In the light control film according to aspects of the present disclosure, the obliquely-stretched base may include cyclo-olefin polymer (COP), tri-acetyl cellulose (TAC), or an acrylic.

In the light control film according to aspects of the present disclosure, the dyes may include three different types of dyes selected from among dye red, dye green, dye blue, dye cyan, dye magenta, or dye yellow.

In the light control film according to aspects of the present disclosure, the horizontally-oriented dye layer may include an acrylate-based resin.

In the light control film according to aspects of the present disclosure, the horizontally-oriented dye layer may further include a photoinitiator.

In the light control film according to aspects of the present disclosure, the single transmittance (Ts) of the horizontally-oriented dye layer may range from 60% to 80%.

According to aspects of the present disclosure, provided is a display device including: a display panel; an obliquely-stretched base disposed on the display panel; a horizontally-oriented dye layer disposed on the obliquely-stretched base and including dyes and a horizontal alignment film integrated with the dyes; and an anti-reflection layer disposed on the horizontally-oriented dye layer, wherein the display panel includes a black bank defining an emission area.

In the display device according to aspects of the present disclosure, the black bank may include at least one selected from among black resin, graphite powder, gravure ink, black spray, or black enamel.

In the display device according to aspects of the present disclosure, the obliquely-stretched base may have a plane-direction phase retardation value (Rin) of 137 nm to 147 nm.

In the display device according to aspects of the present disclosure, the obliquely-stretched base may have the plane-direction phase retardation value (Rin) of 140 nm to 144 nm.

In the display device according to aspects of the present disclosure, an optical axis of the obliquely-stretched base may be range from 30° to 60°.

In the display device according to aspects of the present disclosure, the optical axis of the obliquely-stretched base may be 45°.

In the display device according to aspects of the present disclosure, the obliquely-stretched base may include cyclo-olefin polymer (COP), tri-acetyl cellulose (TAC), or an acrylic.

In the display device according to aspects of the present disclosure, the dyes may include three different types of dyes selected from among dye red, dye green, dye blue, dye cyan, dye magenta, or dye yellow.

In the display device according to aspects of the present disclosure, the horizontally-oriented dye layer may include an acrylate-based resin.

In the display device according to aspects of the present disclosure, the horizontally-oriented dye layer may further include a photoinitiator.

In the display device according to aspects of the present disclosure, the single transmittance (Ts) of the horizontally-oriented dye layer may range from 60% to 80%.

According to aspects of the present disclosure, the light control film and the display device may have improved black vision in an off state by reducing the reflectance of external light.

According to aspects of the present disclosure, the light control film and the display device may have improved outdoor visibility and contrast ratio by reducing the reflectance of external light.

According to aspects of the present disclosure, the light control film and the display device capable of low power consumption may be provided.

It will be apparent to those skilled in the art that various modifications and variations can be made in the light control film and the display device including the same of the present disclosure without departing from the spirit or scope of the aspects. Thus, it is intended that the present disclosure covers the modifications and variations of the aspects provided they come within the scope of the appended claims and their equivalents.

What is claimed is:

1. A light control film comprising:
an obliquely-stretched base;
a horizontally-oriented dye layer disposed on the obliquely-stretched base and comprising dyes and a horizontal alignment film integrated with the dyes; and
an anti-reflection layer disposed on the horizontally-oriented dye layer.

2. The light control film according to claim 1, wherein the obliquely-stretched base has a plane-direction phase retardation value (Rin) of in a range of 137 nm and 147 nm.

3. The light control film according to claim 1, wherein the obliquely-stretched base has the plane-direction phase retardation value (Rin) of in a range of 140 nm and 144 nm.

4. The light control film according to claim 1, wherein an optical axis of the obliquely-stretched base is range from 30° to 60°.

5. The light control film according to claim 4, wherein the optical axis of the obliquely-stretched base is 45°.

6. The light control film according to claim 1, wherein the obliquely-stretched base comprises cyclo-olefin polymer (COP), tri-acetyl cellulose (TAC), or an acrylic.

7. The light control film according to claim 1, wherein the dyes comprise three different types of dyes selected from among dye red, dye green, dye blue, dye cyan, dye magenta, or dye yellow.

8. The light control film according to claim 1, wherein the horizontally-oriented dye layer comprises an acrylate-based resin.

9. The light control film according to claim 1, wherein the horizontally-oriented dye layer further comprises a photoinitiator.

10. The light control film according to claim 1, wherein the single transmittance (Ts) of the horizontally-oriented dye layer ranges from 60% to 80%.

11. A display device comprising:
a display panel;
an obliquely-stretched base disposed on the display panel;
a horizontally-oriented dye layer disposed on the obliquely-stretched base, and comprising dyes and a horizontal alignment film integrated with the dyes; and
an anti-reflection layer disposed on the horizontally-oriented dye layer,
wherein the display panel comprises a black bank defining an emission area.

12. The display device according to claim 11, wherein the black bank comprises at least one selected from among black resin, graphite powder, gravure ink, black spray, or black enamel.

13. The display device according to claim 11, wherein the obliquely-stretched base has a plane-direction phase retardation value (Rin) in a range of 137 nm and 147 nm.

14. The display device according to claim 11, wherein the obliquely-stretched base has the plane-direction phase retardation value (Rin) a range of 140 nm and 144 nm.

15. The display device according to claim 11, wherein an optical axis of the obliquely-stretched base is range from 30° to 60°.

16. The display device according to claim 15, wherein the optical axis of the obliquely-stretched base is 45°.

17. The display device according to claim 11, wherein the obliquely-stretched base comprises cyclo-olefin polymer (COP), tri-acetyl cellulose (TAC), or an acrylic.

18. The display device according to claim 11, wherein the dyes comprise three different types of dyes including dye red, dye green, dye blue, dye cyan, dye magenta, or dye yellow.

19. The display device according to claim 11, wherein the horizontally-oriented dye layer comprises an acrylate-based resin.

20. The display device according to claim 11, wherein the horizontally-oriented dye layer further comprises a photoinitiator.

21. The display device according to claim 11, the single transmittance (Ts) of the horizontally-oriented dye layer ranges from 60% to 80%.
